(19) United States
(12) Patent Application Publication
(10) Pub. No.: US 2025/0311372 A1
(43) Pub. Date: Oct. 2, 2025

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Hiroki SAKATA, Kawasaki Kanagawa (JP); Tatsuya NISHIWAKI, Yokohama Kanagawa (JP)

(21) Appl. No.: 18/821,443

(22) Filed: Aug. 30, 2024

(30) Foreign Application Priority Data
Apr. 2, 2024 (JP) 2024-059675

(51) Int. Cl. H01L 29/78; H01L 29/417; H01L 29/45

(52) U.S. Cl. CPC H10D 64/647; H10D 64/252; H10D 64/62

(57) ABSTRACT

A semiconductor device includes a first electrode; a first semiconductor layer including a plurality of mesa parts; a second electrode positioned in a recess provided in an upper portion of the mesa part; a gate electrode adjacent to the mesa part; an insulating film located between the gate electrode and the mesa part; and a second semiconductor layer contacting an end portion of the second electrode. The mesa part includes a first side surface facing the gate electrode via the insulating film in the first direction, and a second side surface positioned at a side opposite to the first side surface. The second electrode contacts the second side surface.

### CROSS-REFERENCE TO RELATED APPLICATION

This application is based upon and claims the benefit of priority from Japanese Patent Application No. 2024-059675, filed on Apr. 2, 2024; the entire contents of which are incorporated herein by reference.

### FIELD

Embodiments described herein relate generally to a semiconductor device.

### BACKGROUND

Among vertical MOSFETs (Metal-Oxide-Semiconductor Field Effect Transistors), a Schottky MOSFET has been proposed in which a p-type base layer is not included, and an off-state is realized by a depletion layer extending from a Schottky junction between a source electrode and a semiconductor layer at a trench contact part.

### BRIEF DESCRIPTION OF THE DRAWINGS

FIG. 1 is a schematic plan view of a semiconductor device of an embodiment;

FIG. 2 is an enlarged schematic plan view of portion A of FIG. 1;

FIG. 3 is an A-A cross-sectional view of FIG. 2;

FIG. 4 is a B-B cross-sectional view of FIG. 2;

FIG. 5 is a C-C cross-sectional view of FIG. 2;

FIG. 6 is a D-D cross-sectional view of FIG. 2;

FIG. 7 is a schematic plan view of a semiconductor device of a second embodiment;

FIG. 8 is an E-E cross-sectional view of FIG. 7;

FIG. 9 is a schematic plan view of a semiconductor device according to a first modification of a second embodiment;

FIG. 10 is a schematic plan view of a semiconductor device according to a second modification of a second embodiment;

FIG. 11 is a schematic plan view of a semiconductor device according to a third modification of a second embodiment;

FIG. 12 is a schematic plan view of a semiconductor device of a third embodiment; and

FIG. 13 is a F-F cross-sectional view of FIG. 12.

### DETAILED DESCRIPTION

According to one embodiment, a semiconductor device includes a first electrode; a first semiconductor layer located on the first electrode, the first semiconductor layer being of a first conductivity type, the first semiconductor layer including a plurality of mesa parts separated from each other in a first direction, the plurality of mesa parts extending in a second direction orthogonal to the first direction; a second electrode positioned in a recess provided in an upper portion of at least one of the mesa parts, the second electrode extending in the second direction; a gate electrode adjacent to the at least one of the mesa parts in the first direction; an insulating film located between the gate electrode and the at least one of the mesa parts; and a second semiconductor layer contacting an end portion in the second direction of the second electrode, the second semiconductor layer being of a second conductivity type, the at least one of the mesa parts including a first side surface facing the gate electrode via the insulating film in the first direction, and a second side surface positioned at a side opposite to the first side surface in the first direction, the second electrode contacting the second side surface.

Exemplary embodiments will now be described with reference to the drawings. Similar components in the drawings are marked with like reference numerals. In the drawings below, directions are indicated by an X-axis, a Y-axis, and a Z-axis. A direction along the X-axis is taken as a first direction X. A direction along the Y-axis is taken as a second direction Y; and the second direction Y is orthogonal to the first direction X. A direction along the Z-axis is taken as a third direction Z; and the third direction Z is orthogonal to the first and second directions X and Y. In the specification, a width in a specific direction refers to the maximum width in the specific direction.

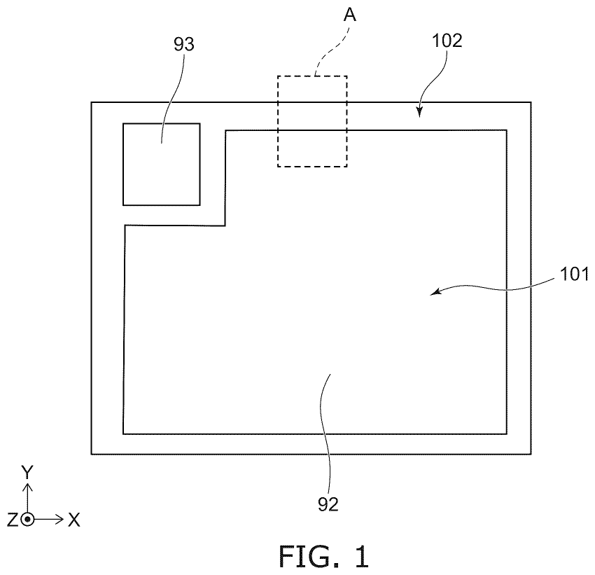

As shown in FIG. 1, semiconductor devices according to embodiments each include an element region 101 and a termination region 102. The termination region 102 continuously surrounds the element region 101. The semiconductor device includes a semiconductor layer. In the specification, a first conductivity type of the semiconductor layer is taken to be an n-type; and a second conductivity type is taken to be a p-type. The first conductivity type may be the p-type; and the second conductivity type may be the n-type. The semiconductor layer is, for example, a silicon layer. Or, the semiconductor layer may be a silicon carbide layer, a gallium nitride layer, etc.

A second electrode 92 and a gate pad 93 are located on the semiconductor layer. The gate pad 93 is electrically connected with the gate electrode, which is described below. For example, wires are bonded respectively to the second electrode 92 and the gate pad 93; and the second electrode 92 and the gate electrode are electrically connected with an external circuit.

### First Embodiment

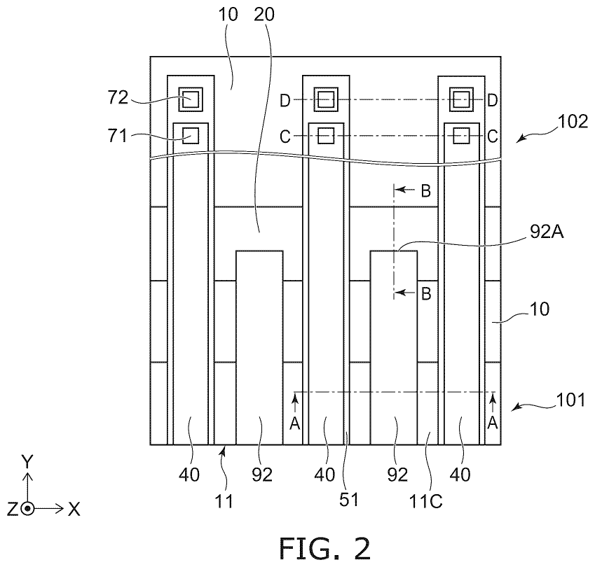

A semiconductor device of a first embodiment will now be described with reference to FIGS. 2 to 6.

FIG. 2 is an enlarged schematic plan view of portion A of FIG. 1. FIGS. 7 and 9 to FIG. 12 below also are enlarged schematic plan views of portion A of FIG. 1.

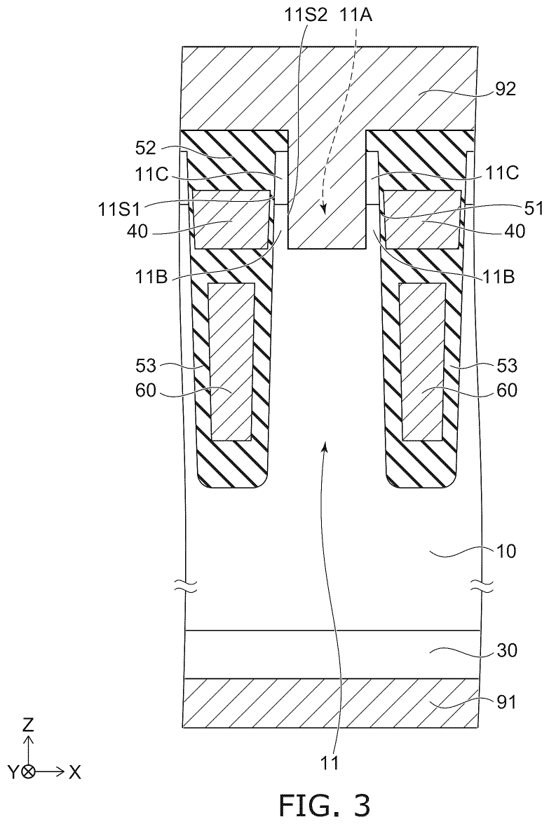

FIG. 3 is an A-A cross-sectional view of FIG. 2.

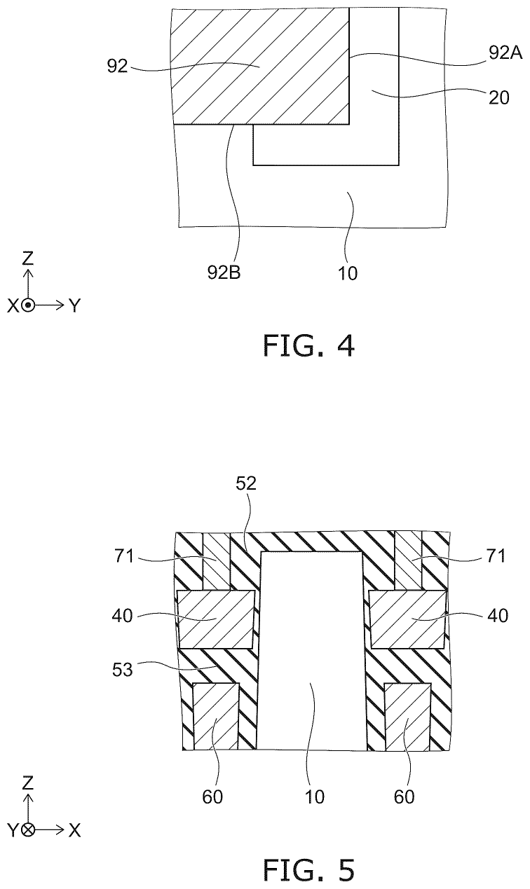

FIG. 4 is a B-B cross-sectional view of FIG. 2.

FIG. 5 is a C-C cross-sectional view of FIG. 2.

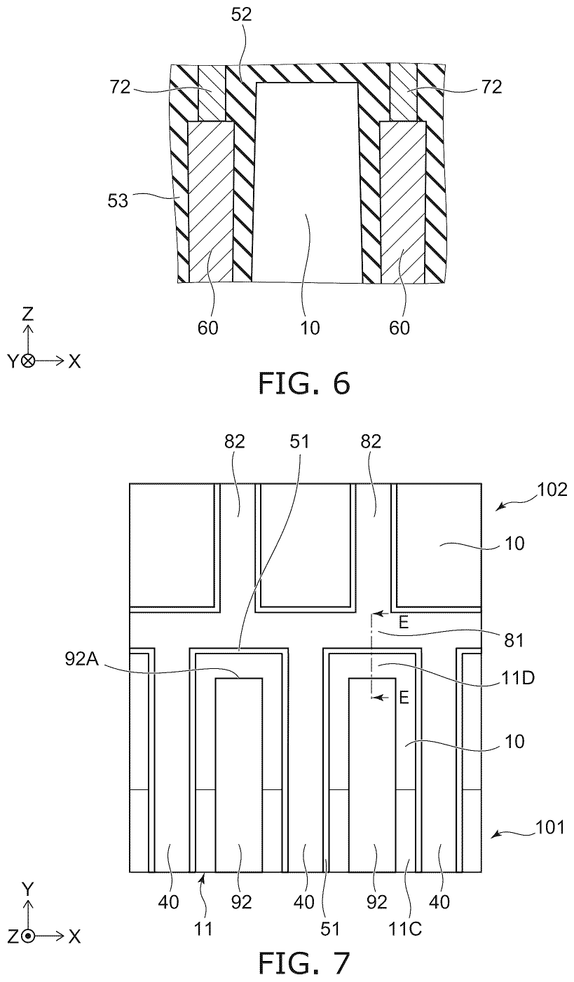

FIG. 6 is a D-D cross-sectional view of FIG. 2.

As shown in FIG. 3, the semiconductor device of the embodiment includes a first electrode 91, an n-type first semiconductor layer 10 located on the first electrode 91, and the second electrode 92 located on the first semiconductor layer 10. The semiconductor device of the embodiment has, for example, a MOSFET (Metal-Oxide-Semiconductor Field Effect Transistor) structure. The first electrode 91 is a drain electrode of the MOSFET; and the second electrode 92 is a source electrode of the MOSFET. For example, a positive potential is applied to the first electrode 91; and 0 V is applied to the second electrode 92. In an on-state in which the gate voltage of a gate electrode 40 is set to be greater than a threshold voltage, a current flows in a vertical direction (a third direction Z) between the first electrode 91 and the second electrode 92 via the first semiconductor layer 10. In the third direction Z, the direction from the first electrode 91 toward the second electrode 92 is taken as up or above; and the direction from the second electrode 92 toward the first electrode 91 is taken as down or below.

The first semiconductor layer 10 includes multiple mesa parts 11 that are separated from each other in the first direction X and extend in the second direction Y. The trench structure parts that include the gate electrodes 40 are adjacent to the mesa parts 11 in the first direction X. The multiple trench structure parts are arranged in the first direction X. Each trench structure part extends in the second direction Y. The mesa parts 11 and the trench structure parts are located in the element region 101.

The second electrode 92 is positioned in a recess 11A provided in the upper portion of the mesa part 11. The recess 11A and the second electrode 92 inside the recess 11A extend in the second direction Y. The second electrode 92 also is located on the trench structure part.

The trench structure part further includes an insulating layer 52 located between the gate electrode 40 and the second electrode 92 in the third direction Z, and a first insulating film 51 located between the mesa part 11 and the gate electrode 40 in the first direction X.

The trench structure part may further include a field plate electrode 60 and a second insulating film 53. The field plate electrode 60 is positioned below the gate electrode 40. The second insulating film 53 is located between the gate electrode 40 and the field plate electrode 60 and between the field plate electrode 60 and the first semiconductor layer 10.

The portion of the mesa part 11 positioned between the trench structure part and the second electrode 92 (the recess 11A) includes a first side surface 11S1 and a second side surface 11S2. The first side surface 11S1 faces the gate electrode 40 via the first insulating film 51 in the first direction X. The second side surface 11S2 is positioned at the side opposite to the first side surface 11S1 in the first direction X. The second electrode 92 contacts the second side surface 11S2 inside the recess 11A.

The portion of the mesa part 11 between the first side surface 11S1 and the second side surface 11S2 includes a channel part 11B and a contact part 11C. The channel part 11B faces the gate electrode 40 via the first insulating film 51 in the first direction X. The contact part 11C is located on the channel part 11B. The n-type impurity concentration of the contact part 11C is greater than the n-type impurity concentration of the channel part 11B. The mesa parts 11 in the element region 101 do not include a p-type semiconductor layer.

The second electrode 92 is made of a metal material. The second electrode 92 and the second side surface 11S2 of the channel part 11B form a Schottky junction. The second electrode 92 directly contacts the second side surface 11S2 of the channel part 11B. Or, the second electrode 92 may contact the second side surface 11S2 of the channel part 11B via an insulating film. The second electrode 92 has an ohmic contact with the second side surface 11S2 of the contact part 11C.

The semiconductor device further includes an n-type third semiconductor layer 30 that is located between the first electrode 91 and the first semiconductor layer 10 and is electrically connected with the first electrode 91. The n-type impurity concentration of the third semiconductor layer 30 is greater than the n-type impurity concentration of the first semiconductor layer 10.

In the on-state in which the gate voltage of the gate electrode 40 is set to be greater than the threshold voltage, a current flows between the first electrode 91 and the second electrode 92 via the contact part 11C and the channel part 11B.

When the gate voltage of the gate electrode 40 is less than the threshold voltage, e.g., 0 V, the channel part 11B is depleted by a depletion layer extending in the first direction X from the Schottky junction between the second electrode 92 and the second side surface 11S2 of the channel part 11B and by a depletion layer extending in the first direction X from the boundary between the second side surface 11S2 of the channel part 11B and the first insulating film 51 of the trench structure part; and the semiconductor device is switched to the off-state.

It is favorable for the width in the first direction X of the channel part 11B to be narrow so that the channel part 11B depletes more easily. For example, the width in the first direction X of the channel part 11B is less than the width in the first direction X of the second electrode 92 inside the recess 11A. The threshold voltage of the semiconductor device is dependent on the width in the first direction X of the channel part 11B. Also, the breakdown voltage and threshold voltage of the semiconductor device are dependent on the barrier height between the first semiconductor layer 10 and the metal of the second electrode 92. By using a metal having a high work function such as, for example, Pt, etc., as the second electrode 92, the barrier height between the second electrode 92 and the first semiconductor layer 10 can be high, and the breakdown voltage can be high.

For example, the semiconductor device of the embodiment can be used as a switching element in applications such as an inverter, motor driving, etc. In such a case, the semiconductor device must have a freewheeling diode function of carrying a reverse current generated when switching. In such a case, it is favorable for the second electrode 92 to contact the first semiconductor layer 10 at the bottom of the recess 11A. As a result, a current path in the freewheeling diode operation (a current path that does not go through the channel part) can be ensured.

The first semiconductor layer 10 also is located in the termination region 102 of the semiconductor device. The contact part 11C is not located in the termination region 102. A p-type second semiconductor layer 20, which is described below, also is located in the termination region 102.

The side surface of the second electrode 92 in the first direction X faces the trench structure part. In contrast, as shown in FIG. 2, an end surface 92A of the second electrode 92 in the second direction Y does not face the trench structure part in the second direction Y. Therefore, a depletion layer cannot extend in the second direction Y from the boundary between the trench structure part and the first semiconductor layer 10 in the region adjacent to the end surface 92A of the second electrode 92. This configuration may cause a leakage current to flow along the end surface 92A of the second electrode 92.

According to the embodiment as shown in FIGS. 2 and 4, the p-type second semiconductor layer 20 that contacts the end portion in the second direction Y of the second electrode 92 is included. The second semiconductor layer 20 is located inside the first semiconductor layer 10 and contacts the end surface 92A and a bottom surface 92B at the end portion in the second direction Y of the second electrode 92. The p-n junction between the second semiconductor layer 20 and the first semiconductor layer 10 can reduce the leakage current in the region adjacent to the end surface 92A of the second electrode 92.

As shown in FIGS. 2 and 5, in the termination region 102, the gate electrode 40 is electrically connected with a not-illustrated gate wiring part located on the insulating layer 52 via a first connection part 71 extending through the insulating layer 52. The gate wiring part is electrically connected with the gate pad 93 shown in FIG. 1.

As shown in FIGS. 2 and 6, in the termination region 102, the field plate electrode 60 is electrically connected with the second electrode 92 located on the insulating layer 52 via a second connection part 72 extending through the insulating layer 52.

### Second Embodiment

A semiconductor device of a second embodiment will now be described with reference to FIGS. 7 to 11. In the description of the semiconductor device of the second embodiment, the same configurations as those of the semiconductor device of the first embodiment are marked with like reference numerals, and the configurations that are different from those of the semiconductor device of the first embodiment are mainly described.

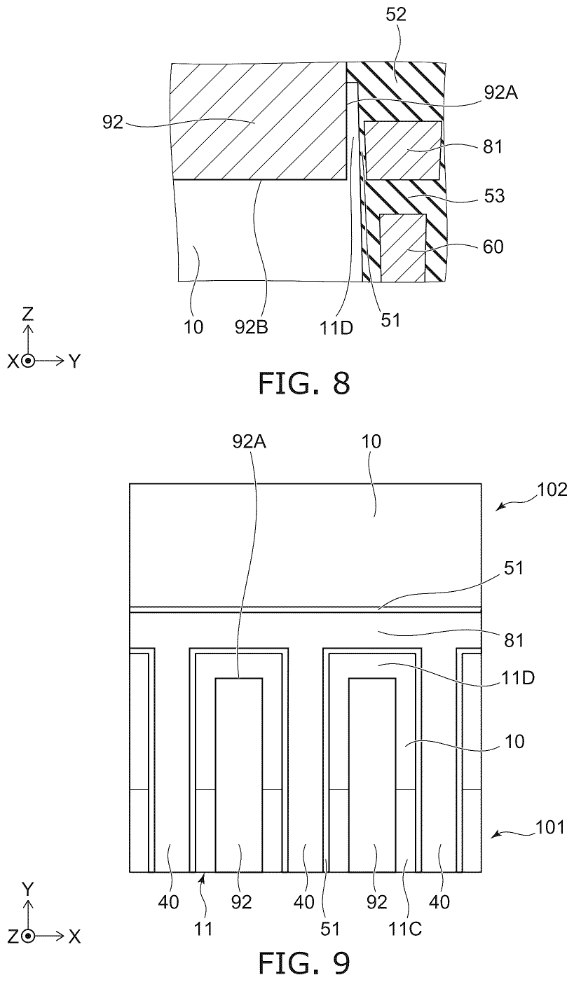

As shown in FIGS. 7 and 8, the semiconductor device of the second embodiment includes a first conductive member 81 that extends in the first direction X in the termination region 102 and faces the end surface 92A of the second electrode 92 in the second direction Y.

A trench structure part similar to that of the element region 101 extends in the first direction X in the termination region 102. For example, the trench structure part of the element region 101 and the trench structure part of the termination region 102 are simultaneously formed. For example, the first conductive member 81 of the trench structure part of the termination region 102 is formed simultaneously with the same material as the gate electrode 40 of the trench structure part of the element region 101. Similarly to the trench structure part of the element region 101, the trench structure part of the termination region 102 includes the first insulating film 51, the second insulating film 53, the field plate electrode 60, and the insulating layer 52.

As shown in FIG. 8, a portion 11D of the first semiconductor layer 10 is located between the first conductive member 81 and the end surface 92A of the second electrode 92 in the second direction Y. The end surface 92A of the second electrode 92 and the portion 11D of the first semiconductor layer 10 form a Schottky junction. The first insulating film 51 is located between the first conductive member 81 and the portion 11D of the first semiconductor layer 10 in the second direction Y.

According to the second embodiment, the portion 11D of the first semiconductor layer 10 can be depleted by a depletion layer extending in the second direction Y from the Schottky junction between the end surface 92A of the second electrode 92 and the portion 11D of the first semiconductor layer 10 and by a depletion layer extending in the second direction Y from the boundary between the first insulating film 51 and the portion 11D of the first semiconductor layer 10. As a result, the leakage current in the region adjacent to the end surface 92A of the second electrode 92 can be reduced. It is favorable for the width in the second direction Y of the portion 11D of the first semiconductor layer 10 to be less than the width in the second direction Y of the first conductive member 81 to make it easier for the portion 11D of the first semiconductor layer 10 to deplete.

For example, the trenches formed in the element region 101 and the trenches formed in the termination region 102 are connected to each other; and the first conductive member 81 is connected with the gate electrode 40 inside the trenches.

In the example shown in FIG. 7, the semiconductor device further includes a second conductive member 82 in the termination region 102 that is connected with the first conductive member 81 and extends in the second direction Y. The gate electrode 40 and the second conductive member 82 extend in mutually-opposite directions from the first conductive member 81. The gate electrode 40 extends from the first conductive member 81 toward the element region 101; and the second conductive member 82 extends from the first conductive member 81 toward the termination of the semiconductor device.

For example, the trench structure part that includes the gate electrode 40, the trench structure part that includes the first conductive member 81, and the trench structure part that includes the second conductive member 82 are formed by the same process. The gate electrode 40, the first conductive member 81, and the second conductive member 82 are simultaneously formed of the same material. Similarly to the trench structure part of the element region 101, the trench structure part that includes the second conductive member 82 includes the first insulating film 51, the second insulating film 53, the field plate electrode 60, and the insulating layer 52.

Similarly to FIG. 5, the end portion in the second direction Y of the second conductive member 82 can be connected with the gate wiring part and the gate pad 93 via the first connection part 71. Accordingly, the gate electrode 40 is electrically connected with the gate wiring part and the gate pad 93 via the first and second conductive members 81 and 82.

The field plate electrode 60 is continuous below the gate electrode 40, below the first conductive member 81, and below the second conductive member 82. Similarly to FIG. 6, the end portion in the second direction Y of the field plate electrode 60 positioned below the second conductive member 82 is connected with the second electrode 92 via the second connection part 72.

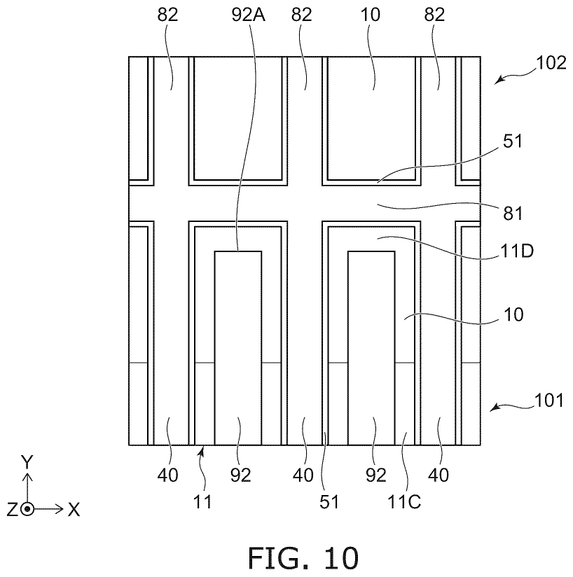

In the example shown in FIG. 7, positions of the gate electrode 40 extending in the second direction Y and the second conductive member 82 extending in the second direction Y are shifted from each other in the first direction X. Or, as shown in FIG. 10, the trench structure part that extends in the first direction X and the trench structure part that extends in the second direction Y may intersect in a cross shape. Compared to the trench layout of FIG. 10, in the trench layout of FIG. 7, the fillability when filling a conductive material used to form the gate electrode 40, the first conductive member 81, and the second conductive member 82 into the trenches that are collectively formed can be improved.

As shown in FIG. 9, the second conductive member 82 may not be included. The trench structure part that includes the gate electrode 40 and extends in the second direction Y and the trench structure part that includes the first conductive member 81 and extends in the first direction X connect in a T-shape.

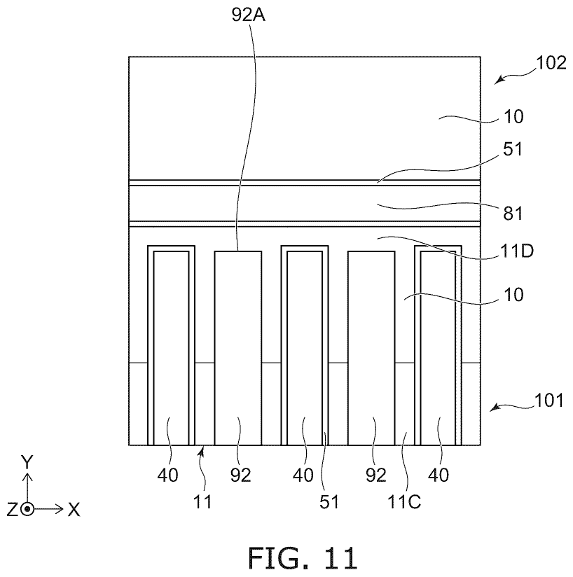

As shown in FIG. 11, the trench structure part that includes the gate electrode 40 and extends in the second direction Y and the trench structure part that includes the first conductive member 81 and extends in the first direction X may not be connected.

### Third Embodiment

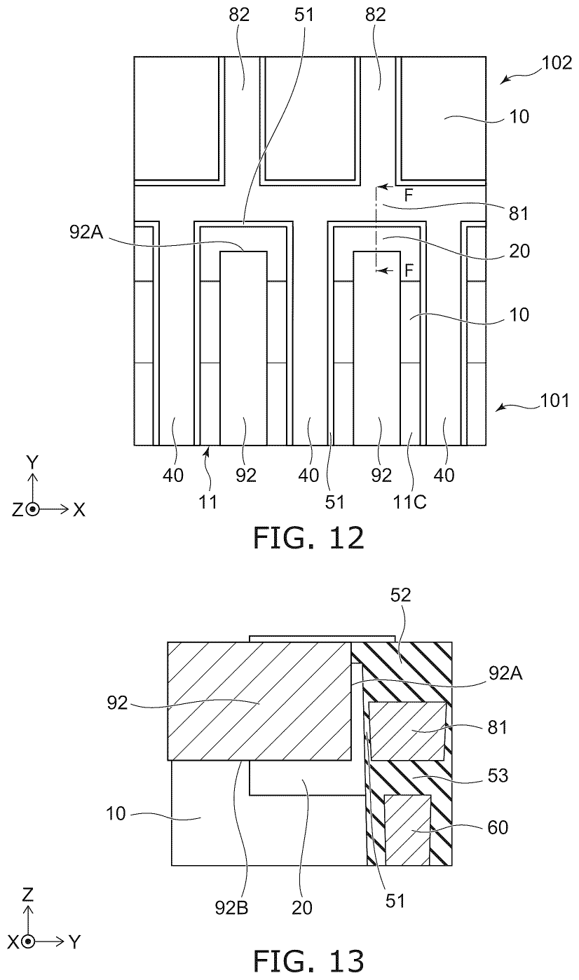

A semiconductor device of a third embodiment will now be described with reference to FIGS. 12 and 13. The configuration of the semiconductor device of the third embodiment combines the p-type second semiconductor layer 20 of the first embodiment and the trench structure part including the first conductive member 81 of the second embodiment.

In the termination region 102, the second semiconductor layer 20 is positioned between the first conductive member 81 and the end surface 92A of the second electrode 92 in the second direction Y. The second semiconductor layer 20 contacts the end surface 92A and the bottom surface 92B of the end portion in the second direction Y of the second electrode 92.

The second semiconductor layer 20 is located between the first conductive member 81 and the end surface 92A of the second electrode 92 in the second direction Y. The first insulating film 51 is located between the second semiconductor layer 20 and the first conductive member 81 in the second direction Y.

According to the third embodiment, a depletion layer that extends in the second direction Y from the boundary between the second semiconductor layer 20 and the first insulating film 51 can deplete the second semiconductor layer 20 adjacent to the end surface 92A of the second electrode 92. The p-n junction between the second semiconductor layer 20 and the first semiconductor layer 10 can reduce the leakage current in the region adjacent to the end surface 92A of the second electrode 92.

According to the first and third embodiments, the second semiconductor layer 20 and the end surface 92A of the second electrode 92 can form a Schottky junction according to the work function of the metal of the second electrode 92 and/or the impurity concentration of the second semiconductor layer 20. In such a case, the depletion layer can spread from the interface between the second semiconductor layer 20 and the end surface 92A of the second electrode 92.

The film thickness of the first insulating film 51 in the termination region 102 may be greater than the film thickness of the first insulating film 51 in the element region 101. The breakdown voltage can be increased thereby.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device, comprising:
a first electrode;
a first semiconductor layer located on the first electrode, the first semiconductor layer being of a first conductivity type, the first semiconductor layer including a plurality of mesa parts separated from each other in a first direction, the plurality of mesa parts extending in a second direction orthogonal to the first direction;
a second electrode positioned in a recess provided in an upper portion of at least one of the mesa parts, the second electrode extending in the second direction;
a gate electrode adjacent to the at least one of the mesa parts in the first direction;
an insulating film located between the gate electrode and the at least one of the mesa parts; and
a second semiconductor layer contacting an end portion in the second direction of the second electrode, the second semiconductor layer being of a second conductivity type,
the at least one of the mesa parts including
a first side surface facing the gate electrode via the insulating film in the first direction, and
a second side surface positioned at a side opposite to the first side surface in the first direction, the second electrode contacting the second side surface.

2. The device according to claim 1, wherein
the at least one of the mesa parts includes:
a channel part positioned between the gate electrode and the second electrode in the first direction; and
a contact part located on the channel part, the contact part having a higher first-conductivity-type impurity concentration than the channel part.

3. The device according to claim 2, wherein
the channel part and the second electrode form a Schottky junction, and
the second electrode has an ohmic contact with the contact part.

4. A semiconductor device, comprising:
a first electrode;
a first semiconductor layer located on the first electrode, the first semiconductor layer being of a first conductivity type, the first semiconductor layer including a plurality of mesa parts separated from each other in a first direction, the plurality of mesa parts extending in a second direction orthogonal to the first direction;
a second electrode positioned in a recess provided in an upper portion of at least one of the mesa parts, the second electrode extending in the second direction;
a gate electrode adjacent to the at least one of the mesa parts in the first direction;
an insulating film located between the gate electrode and the at least one of the mesa parts; and
a first conductive member extending in the first direction, the first conductive member facing an end portion in the second direction of the second electrode,
the at least one of the mesa parts including
a first side surface facing the gate electrode via the insulating film in the first direction, and
a second side surface positioned at a side opposite to the first side surface in the first direction, the second electrode contacting the second side surface.

5. The device according to claim 4, further comprising:
a second semiconductor layer positioned between the first conductive member and the end portion of the second electrode in the second direction,
the end portion of the second electrode contacting the second semiconductor layer,
the second semiconductor layer being of a second conductivity type.

6. The device according to claim 4, wherein
the first conductive member is connected with the gate electrode.

7. The device according to claim 6, further comprising:
a second conductive member connected with the first conductive member, the second conductive member extending in the second direction,
the gate electrode and the second conductive member extending from the first conductive member in mutually-opposite directions.

8. The device according to claim 7, wherein
positions of the gate electrode and the second conductive member are shifted from each other in the first direction.

9. The device according to claim 4, wherein
the at least one of the mesa parts includes:
a channel part positioned between the gate electrode and the second electrode in the first direction; and
a contact part located on the channel part, the contact part having a higher first-conductivity-type impurity concentration than the channel part.

10. The device according to claim 9, wherein
the channel part and the second electrode form a Schottky junction, and
the second electrode has an ohmic contact with the contact part.
